(19) United States
(12) Patent Application Publication
(10) Pub. No.: US 2012/0310573 A1
(43) Pub. Date: Dec. 6, 2012

(54) METHOD TO ESTIMATE A SIGNAL TO INTERFERENCE PLUS NOISE RATIO BASED ON SELECTION OF THE SAMPLES AND CORRESPONDING PROCESSING SYSTEM

(75) Inventors: Stefania Sesia, Roquefort Les Pins (FR); Andrea Ancora, Nice (FR)

(73) Assignee: ST-ERICSSON SA, Plan-les-Ouates (CH)

(21) Appl. No.: 13/505,267

(22) PCT Filed: Nov. 5, 2010
(86) PCT No.: PCT/EP10/06872

§ 371 Date: Aug. 24, 2012

(30) Foreign Application Priority Data
Nov. 9, 2009 (EP) 09306070.5

(51) Int. Cl. G01R 29/26; G06F 19/00

(52) U.S. Cl. 702/69

(57) ABSTRACT

A method to estimate a signal to interference plus noise ratio (SINR) based on selection of the samples and corresponding processing system is provided. The method estimates SINR of an incident signal on a time interval. Samples of the incident signal are received during a time interval. Then, the SINR of the received samples is determined using an average calculation and a variance calculation that includes only a selected set of samples from the received samples. Additionally, the average calculation and/or said variance calculation may be performed by using only the selected set of samples.

### CROSS-REFERENCE TO RELATED APPLICATIONS

This application is a U.S. National Phase application submitted under 35 U.S.C. §371 of Patent Cooperation Treaty application serial no. PCT/EP2010/066872, filed Nov. 5, 2010, and entitled METHOD TO ESTIMATE A SIGNAL TO INTERFERENCE PLUS NOISE RATIO BASED ON SELECTION OF THE SAMPLES AND CORRESPONDING PROCESSING SYSTEM, which application claims priority to European patent application serial no. 09306070.5, filed Nov. 9, 2009, and entitled METHOD TO ESTIMATE A SIGNAL TO INTERFERENCE PLUS NOISE RATIO BASED ON SELECTION OF THE SAMPLES AND CORRESPONDING PROCESSING SYSTEM.

Patent Cooperation Treaty application serial no. PCT/EP2010/066872, published as WO 2011/054918, and European patent application serial no. 09306070.5, are incorporated herein by reference.

### TECHNICAL FIELD

The invention relates to digital signal processing and more particularly to an estimation of the signal to noise plus interference ratio (SINR) in a digital modulated signal.

### BACKGROUND

A non limitative application of the invention is directed to the wireless communication field, in particular the HSDPA (High Speed Downlink Packet Access) and 3G standards. HSDPA is a standard that enables a high data throughput of the downlink. This is made possible by link adaptation and the use of turbo code for FEC (Forward Error Correction).

Link adaptation comprises the adaptation of the modulation and coding rate used for the transmission. The adaptation for the downstream link is done by the base station. It is based on the CQI (Channel Quality Information) feedback reported to the base station by the mobile phone. The CQI calculation is partially based on the SINR (Signal to Interference Plus Noise Ratio) estimation of the pilot sequence received by the mobile phone.

FEC allows the receiver to detect and correct errors without the need to ask the sender for additional data. The use of turbo code enables a better detection and correction. To realize the turbo decoding the mobile is using well-known variables called “soft bits” expressing a trust degree. The soft bit calculation is based on SINR estimation of the data sequence received by the mobile phone.

Therefore, the SINR estimation plays an important role and a correct SINR estimation enables a good quality of service of the HSDPA link.

In the prior art, several algorithms are proposed to estimate the SINR.

One of these algorithms is based on the maximum likelihood. According to the position of the received signal in a constellation, the value of the data sent is identified according to a maximum likelihood. From this value, the average value of the amplitude of data is determined. Then, a variance estimator based on the pilot sequence is used to determine the SINR.

The general drawback of these processes is the miss estimation of the SINR.

### SUMMARY

In view of the foregoing, it is described here a method and a system enabling a better SINR estimation without any significant rise of the complexity.

It is actually proposed a method based on the estimation done only on a selected amount of samples. In particular, only the most reliable samples are selected for the SINR estimation.

According to a first aspect, it is proposed a method for estimating a signal to interference plus noise ratio, called SINR, of an incident signal on a time interval, comprising receiving samples of said incident signal during said time interval and determining said SINR from said received samples using an average calculation and a variance calculation.

According to a general feature, the said determining step comprises selecting a set of samples from said received samples and performing said average calculation and/or said variance calculation by using said selected set of samples only.

Only the most reliable sample is kept and the probability of miss identification is drastically diminished, yielding to a better SINR estimation.

In an embodiment, the said incident signal is a modulated signal and both said average calculation and said variance calculation are performed using said selected set of samples only, maximum likelihood values of said samples obtained from the position of said samples in the modulation constellation and a known sequence of transmitted reference samples.

In another embodiment, the said selection step is performed iteratively until the difference between the current average value of samples calculated on a current selected set of samples and the preceding average value of samples calculated on the preceding selected set of samples is smaller than a threshold.

In another embodiment, said selecting step comprises withdrawing samples subjected to interference intersymbol for obtaining at least one group of samples, and said variance calculation is based on curve fitting with minimum squared error on said at least one group of samples.

The identification of a group suppresses the problem of miss identification of a single sample and the withdraw of samples subjected to interference intersymbol enables a reduction of the contribution of interference in noise calculation which overestimates this calculation. Therefore, a more accurate estimation of SINR with the curve fitting method and the selection is realized.

Advantageously, the curve used for curve fitting is a Gaussian.

According to another embodiment, a supplementary average calculation of at least one group of samples is performed using the result of said variance calculation.

Said curve fitting step and said supplementary average calculation are advantageously performed iteratively, wherein a current variance calculation uses the result of a preceding supplementary average calculation.

According to an another aspect, it is proposed a device for estimating a signal to interference plus noise ratio, called SINR, of an incident signal on a time interval, comprising:

reception means for receiving samples of said incident signal during said time interval

processing means for determining SINR from said received samples, said processing means comprising first calculation means for performing an average calculation and second calculation means for performing a variance calculation.

According to a general feature of this aspect, said processing means comprises selection means for selecting a set of samples from said received samples and said first calculation and/or said second calculation means are configured to use said selected set of samples only.

In an embodiment, the incident signal is a modulated signal, and said first and second calculation means are configured to use said selected set of samples, maximum likelihood values of said samples obtained from the position of said samples in the modulation constellation and a known sequence of transmitted reference samples.

In another embodiment, the selection means comprises comparison means for comparing the difference between a current average value of samples calculated on a current selected set of samples and a preceding average value of samples calculated on a preceding selected set of samples with a threshold and control means configured to activate said selection means until said difference is smaller than said threshold.

In another embodiment, the selection means is configured to withdraw the sample subjected to interference intersymbol in order to obtain at least one group of samples, and the second calculation means comprises means for curve fitting said at least one group of samples with minimum squared error.

According to another embodiment, the means for curve fitting are configured to curve fit the said at least one group of samples with a Gaussian distribution.

According to another embodiment, the processing means comprises third calculation means for performing a supplementary average calculation of at least one group of samples using the variance calculated by said second calculation means.

The processing means further comprises advantageously control means for iteratively activating said means for curve fitting and said third calculation means.

According to another aspect, it is proposed a wireless apparatus comprising a device as defined above.

### BRIEF DESCRIPTION OF THE DRAWINGS

Other advantages and features of the invention will appear on examining the detailed description of embodiments, these being in no way limiting, and of the appended drawings, in which:

FIG. 1 illustrates a general process applied to a digital sequence in a HSDPA wireless communication system;

FIG. 2 illustrates diagrammatically a first embodiment of a method according to the invention;

FIG. 3 illustrates diagrammatically a first embodiment of a device according to the invention;

FIG. 4 illustrates another embodiment of a method according to the invention;

FIGS. 5 and 6 illustrate results related to the embodiment of FIG. 4; and

FIG. 7 illustrates another embodiment of a device according to the invention.

### DETAILED DESCRIPTION

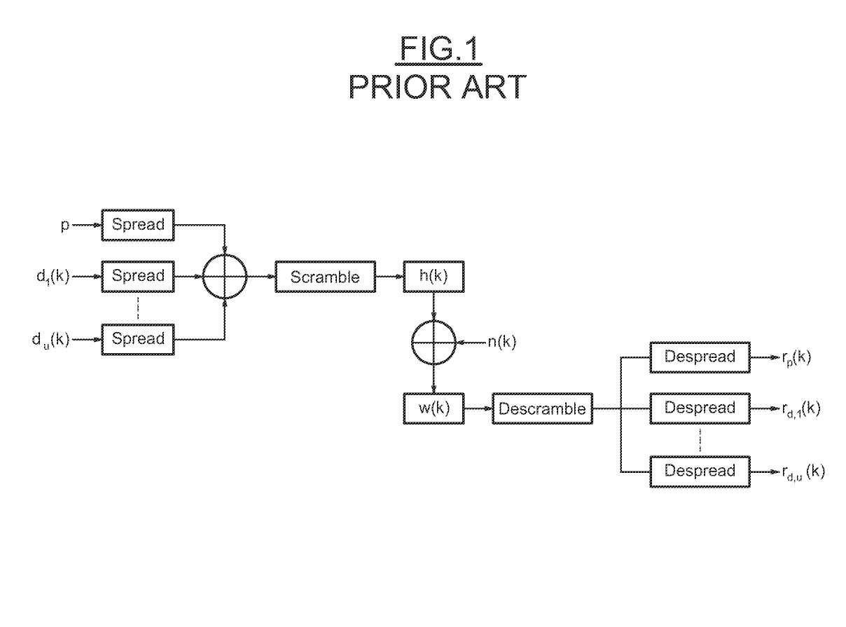

FIG. 1 illustrates a conventional process applied to the digital sequences sent and received in a wireless communication system according to the HSDPA standard.

As it is well known, symbols are sent within successive frames, each frame being subdivided in several slots. Each slot contains a specified number of symbols, each symbol comprises a predetermined number of chips.

The pilot sequence p and the symbol sequence of each user s1, s2 . . . , su (where u is the number of users) are spread with their own spreading codes, summed up and scrambled. The channel is denoted as h and the white Gaussian noise as n. An equalizer w is implemented before descrambling and despreading. The received pilot sequence and the received sequences of chips after descrambling and despreading are called respectively rp and rd,1 . . . rd,u. Therefore, according to FIG. 1, the generic formula for the received sequence of chips rd,u can be written as:

$${r}_{d , u} [ k ] = {d}_{u} [ k ] ( {\sum }_{m = 1}^{SF} \{ {g}_{d} [ k + m ] \} + {ISI}_{d , u} [ k + m ] ) + ISI [ k ] + \tilde{n} [ k ] \qquad ( 1 )$$

In this formula, the data symbol dᵤ[k], corresponding to the k-th chip of user u, is weighted with the principal tap g_{d}[k+m] of the convolution of the channel and the equalizer for time instant ‘k’. The constructive intersymbol interference is given by the pre- and post-cursors ISI_{d,u}[k+m] and is considered as an useful term. However, its contribution is in general negligible. The convolution of the channel, and the equalizer for the chip k is realized considering a spreading factor SF=16. The term ISI[k]+ñ[^{k}]represents the filtered noise and the intersymbol interference.

In general, several codes are associated to one user. If Ncodes is the number of codes allocated to one user, and with a spreading factor of 16, each group of 10 symbols (one slot) contains 10*16*Ncodes chips.

According to the prior art, in the maximum likelihood process, used for determining the SINR, the received chips are processed as followed; on the basis of a procedure of derotation in order to calculate an average value Ā of their amplitude:

$${r}_{derot} [ k ] = {r}_{d} [ k ] \cdot {r}_{ref}^{*} [ k ] \\ {r}_{ref} [ k ] ∈ \{ ( 1 + j ) / \sqrt{2} ; ( 1 - j ) / \sqrt{2} ; ( - 1 + j ) / \sqrt{2} ; ( - 1 - j ) / \sqrt{2} \} \\ A [ k ] = e \{ {r}_{derot} [ k ] \} \\ \overline{A} = \frac{1}{160 {N}_{codes}} {\sum }_{k = 1}^{160 {N}_{codes}} A [ k ] \qquad ( 2 )$$

Where,

rd[k] is the amplitude of the received chip k associated to the user d

rref[k] corresponds to the maximum likelihood value of rd[k] and the value of rref[k] is obtained from a hard decision and depends on the quadrant where the receiving signal belongs. In other words, the value rref[k] corresponds to the position of rd[k] in the constellation.

* is the conjugate complex

Re{ } is the real part operator

Ā is the average value of A[k] calculated on 160×Ncodes chips.

Then SINR calculation can be done by a ratio between the average value squared Ā² and a variance value involving the average value Ā and the pilot sequence. For one slot, the SINR with maximum likelihood identification can be computed by:

$${SINR}_{ML} = \frac{{\overline{A}}^{2}}{\frac{1}{160 {N}_{codes}} {\sum }_{k = 1}^{160 {N}_{codes}} {\vert {r}_{p} [ k ] - \overline{A} \cdot p [ k ] \vert}^{2}} \qquad ( 3 )$$

Where:

p[k] are the transmitted chips of the pilot sequence

rp[k] are the received chips of the pilot sequence.

The problem of this method is the overestimation of the SINR particularly in a low SINR region. The maximum likelihood method is biased because the maximum likelihood-based identification of one sample chip can be false. In order to overcome the problem a modified maximum likelihood method is proposed based only on a selected amount of samples, and more precisely the samples that are the most reliable.

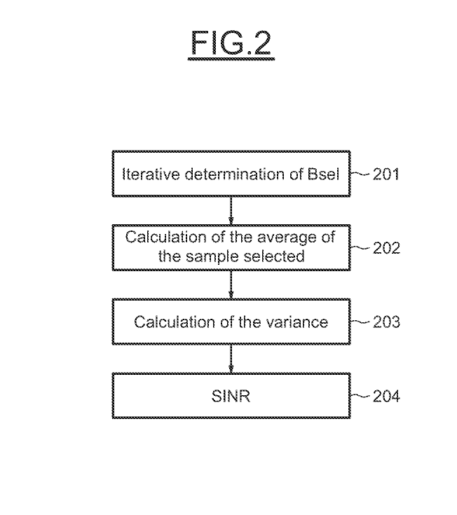

FIG. 2 illustrates an embodiment of such a modified likelihood method.

In fact, the average value mentioned in (2) above will be calculated only on a selected group of samples Bsel. Here, Bsel is obtained iteratively after the derotation of 160×Ncodes symbols (step 201). More precisely, Bsel,n denotes the current group of samples selected at iteration n. Its samples are described by:

B_{sel,n}={A[k], with k such that |rₚ[k]−αₙ₋₁|²≦rₙ₋₁²} (4)

where rp[k] is the received chips of the pilots sequence, A[k] is defined in (2) above, αₙ₋₁ is the average of the A[k]∈Bsel,n−1 defined as follows

$${a}_{n - 1} = \frac{1}{{N}_{sel}} {\sum }_{{B}_{sel , n - 1}} A [ k ] and {r}_{n - 1} = \frac{{a}_{n - 1}}{2} \qquad ( 5 )$$

and Nsel is the number of sample of the previous group Bsel,n−1.

The samples selected lie within the complex plan on a disc centered on an and with a radius rn. At the initialization step, all samples A[k] are considered. This selection is easy to implement and enables to select samples close to the average, which are less affected by the noise.

The iterations are going on until the difference Δ=αₙ−αₙ₋₁ is lower than a predefined threshold δ. For a δ=0.01, only one or two iterations are necessary to reach the desired threshold.

Then, a step 202 of average calculation is performed. The average of the selected group of samples Bsel can be calculated as following:

$${\overline{A}}_{sel} = \frac{1}{{N}_{sel}} {\sum }_{{B}_{sel}} A [ k ] .$$

Asel represents also an attenuation coefficient of the channel. Finally, a step 203 of variance calculation is performed. The variance can be computed with the following formula:

$$\frac{1}{160 {N}_{codes}} {\sum }_{k = 1}^{160 {N}_{codes}} {\vert {r}_{p} [ k ] - {\overline{A}}_{sel} \cdot p [ k ] \vert}^{2}$$

The SINR for one slot can be then easily calculated (step 204) as the following ratio:

$${SINR}_{MML} = \frac{{( {\overline{A}}_{sel} )}^{2}}{\frac{1}{160 {N}_{codes}} {\sum }_{k = 1}^{160 {N}_{codes}} {\vert {r}_{p} [ k ] - {\overline{A}}_{sel} \cdot p [ k ] \vert}^{2}} \qquad ( 6 )$$

In other words, this method of Modified Maximum Likelihood (MML) enables a more accurate SINR estimation than the maximum likelihood (ML) method according to the prior art. This method comprises the adding of one selection step before the process of maximum likelihood. The selection is easy to compute based on an iterative process (cf. (4)).

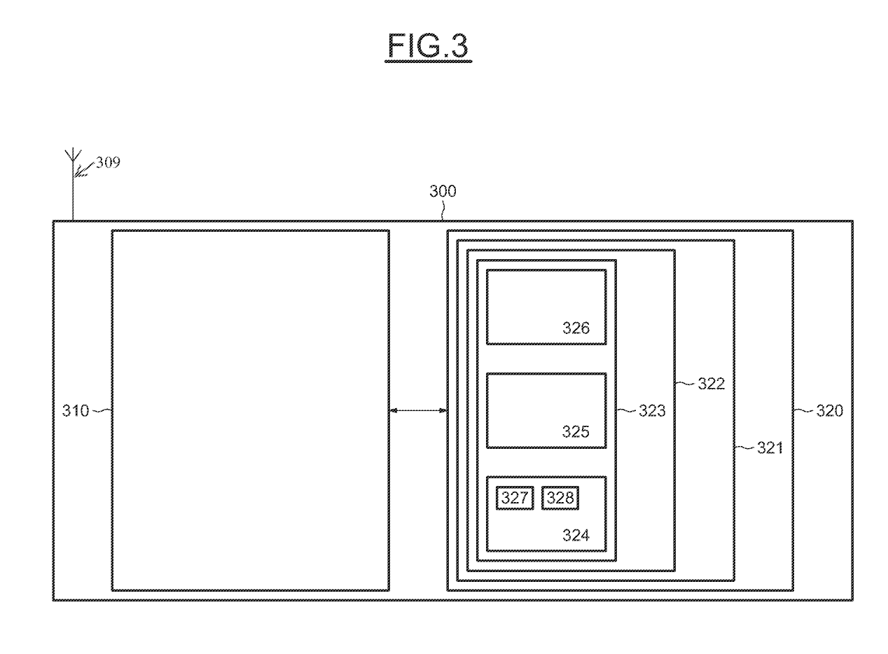

FIG. 3 illustrates diagrammatically a wireless apparatus including a device capable of implementing a modified maximum likelihood method according to the invention. The apparatus 300 comprises conventionally an antenna 309, an analog stage 310 and a digital stage 320. The antenna is able to emit and/or receive analog modulated signals. The analog stage comprises conventional means for analog modulation and demodulation.

The digital stage includes, for example, a base-band processor 321. The digital stage comprises a device 322 for estimating a signal to interference plus noise ratio (SINR). This device may be realized by software modules within the base-band processor.

The device 300 comprises reception means for receiving the digital samples of the incident signal. The device also comprises processing means 323 for determining SINR from said received samples. The processing means 323 comprise selection means 324 for selecting a set of samples from said received samples, a first calculation means 325 for performing an average calculation and second calculation means 326 for performing a variance calculation. Said first calculation and/or said second calculation means are configured to use said selected set of samples only.

According to one embodiment, first calculation and/or said second calculation means use the maximum likelihood values of said selected set of samples. The maximum likelihood is obtained from the position of the samples in the modulation constellation. With the maximum likelihood value and a known sequence of transmitted reference samples, the first calculation means 325 and/or second calculation means 326 can perform a variance and average calculation of said selected set of samples.

The selection means 324 can comprise comparison means 327. They can also comprise control means 328 configured to activate said selection means iteratively. During each selection, the difference between a current average value of samples calculated on a current selected set of samples and a preceding average value of samples calculated on a preceding selected set of samples is compared by the means of comparison 327 with a threshold. The selection is iterated by the control means 328 until the said difference is smaller than said threshold.

The processing means 323 and several means described above may be realized by software modules within the base-band processor 321.

Another improvement of the SINR calculation with respect to the conventional ML method is based on curve fitting which is now described.

The curve fitting consists of an identification of the probability density function of the received samples with a reference curve. For exemplary purpose, a Gaussian is chosen as the reference curve to be fitted, but another reference curve can also be used. The curve fitting identification of the probability density function can be based on a Minimum Mean Squared Error.

In this method, according to a first advantage, the risk of a false maximum likelihood identification of one sample is reduced because the curve fitting proposes to identify a probability density function of a group of samples.

According to a second advantage, the calculated SINR is more accurate because only the received samples that are less affected by interference are selected for the curve fitting.

The calculation of the SINR according to curve fitting is applied here to the case of 2-PAM (pulse amplitude modulation containing a mapping of signal with only two levels of amplitude). From the calculation of the SINR of a 2-PAM transmission, the SINR of QPSK transmission used in HSDPA can be deducted. Actually, the QPSK modulation can be seen as the concatenation of two PAM modulations (one for the real part and the other for the imaginary part). The method exposed here can be generalized to the SINR calculation of any QAM modulation transmission by the man of ordinary skill.

In order to enable a fast deduction of QPSK SINR, the 2-PAM (pulse amplitude modulation) received samples are considered with a doubled number of samples. Let y(ts)=(y[1], y[2], . . . , y[k], . . . y[2·160·Nᵤₛₑᵣ]) with k=1,2, . . . 2·160·N_{codes} be the vector representing all the real and imaginary components of rd[k] in one slot ts. Each sample y[k] corresponds to the receiving amplitude of one of the two levels used in the 2-PAM.

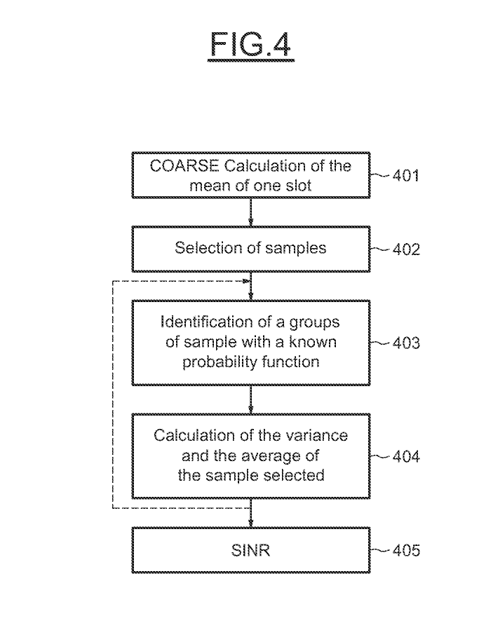

FIG. 4 illustrates a flowchart of the process. To sum up, this process contains a step of mean (average) calculation 401, a step of selection of two groups of samples 402, and then a determination of the probability density function of the samples of these groups 403. Subsequently, this probability density function will be identified by curve fitting with a Gaussian distribution whose average and mean squared error will be determined 404. This determination enables the calculation of the SINR of the samples y[k] 405.

The calculation of the SINR can be made with the samples of one selected group only, whatever the selected group, or on the samples of both selected groups, thus increasing the number of samples.

An example of SINR calculation will be now described using only one group among the two selected groups with reference to FIGS. 4, 5 and 6.

First, a coarse estimation of the mean (average) of the received samples on the slot ts is performed (step 401). The mean m0(ts) is estimated by simply averaging the absolute value of all the samples y[k] (chips) of the slot ts:

$${m}_{0} ( ts ) = \frac{{\sum }_{i = 1}^{320 {N}_{codes}} \vert y [ k ] \vert}{320 {N}_{codes}} \qquad ( 7 )$$

Then, a selection of samples (402) is performed. To do such, the elements are selected as:

$$Selection = \{ y [ k ] , such that \vert y [ k ] \vert > θ \} , \\ with θ set such that \frac{numbers of samples of \{ Selection \}}{2 {N}_{codes} 160} \approx 0.25 \qquad ( 8 )$$

Two groups are thus created:
a first group of samples whose amplitude is greater than θ verifying y[k]>θ
a second group of samples whose amplitude is smaller than −θ verifying y[k]<−θ

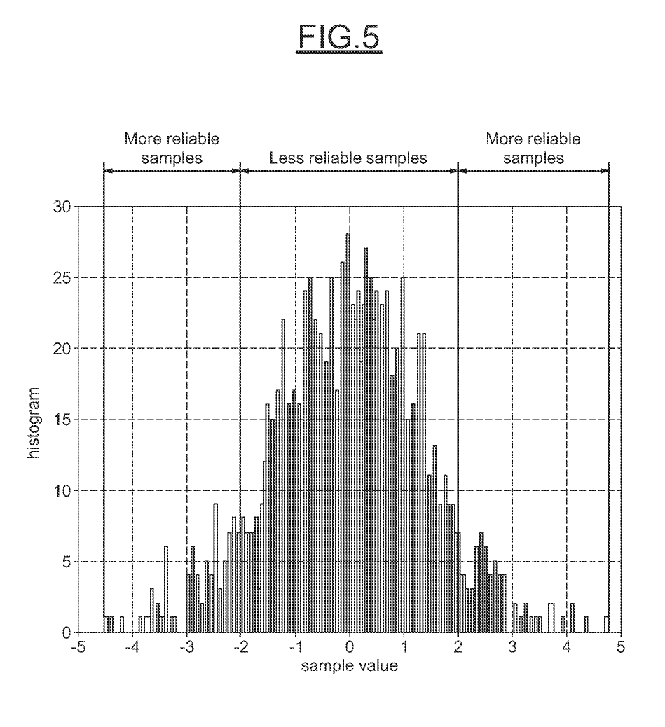

Each of these two groups corresponds to the “more reliable” groups illustrated hereafter in FIG. 5.

The selection enables a more accurate estimation of SINR. Actually, the samples in of one these two selected groups are less affected by interference. Therefore, in the estimation of SINR, the influence of interference is minimized.

Now, as an example, one of these groups is chosen for the SINR calculation. As it will be explained more in details thereafter, an aim of this method consists in finding the Gaussian that fits the best the probability density function of the samples of this group. And then, the variance of the samples of the groups will be the variance of the found Gaussian curve. More details are now described.

The samples of one this chosen groups are plotted on a histogram in which the horizontal axis corresponds to the amplitude of the sample and the vertical axis corresponds to the number of event.

The histogram of the group of samples is then divided into several bins Cᵢ=[sᵢ,sᵢ₊₁]=[θ+(i−1)·Δ; θ+i·Δ] where

$$Δ = \frac{Max ( \vert y [ k ] \vert ) - θ}{{N}_{bins}}$$

and where Nbins is the number of bins, for example 10.

An empirical probability density function can then be computed by counting how many samples belong to each bin Ci. This is called zi, i.e.

$${z}_{i} = \frac{{\sum }_{k = 1}^{320 {N}_{codes}} 1 \{ y [ k ] ∈ {C}_{i} \}}{320 {N}_{codes}} \qquad ( 9 )$$

Where 1 {.} is the indicator function equal to 1 if the condition in bracket is verified and zero otherwise. This operation provides Nbins empirical points.

The identification, 403, with the Gaussian probability density function that fits the best those empirical points is now described.

As the mean has already been coarsely estimated, the only parameter that needs to be calculated is the mean squared (square root of the variance) of the Gaussian.

The mean squared error between the empirical density function and the Gaussian to be determined is given by the following formula:

$$\begin{matrix}J = {\sum }_{i = 1}^{{N}_{bins}} {[ {z}_{i} - Pr ( y [ k ] ∈ {C}_{i} ) ]}^{2} \\ = {\sum }_{i = 1}^{{N}_{bins}} {[ {z}_{i} - Q ( \frac{{s}_{i}}{\sqrt{{σ}^{2}}} ) + Q ( \frac{{s}_{i + 1}}{\sqrt{{σ}^{2}}} ) ]}^{2} \\ = {\sum }_{i = 1}^{{N}_{bins}} {[ {z}_{i} - Q ( \frac{{s}_{i}}{\sqrt{{σ}^{2}}} ) + Q ( \frac{{s}_{i + 1}}{\sqrt{{σ}^{2}}} ) ]}^{2} \\ = {\sum }_{i = 1}^{{N}_{bins}} {[ {z}_{i} - Q ( \frac{θ + ( i - 1 ) Δ - {m}_{0}}{\sqrt{{σ}^{2}}} ) + Q ( \frac{θ + i Δ - {m}_{0}}{\sqrt{{σ}^{2}}} ) ]}^{2}\end{matrix} \qquad ( 10 )$$

J is the metric that needs to be minimized. A minimum according to σ2 is necessarily verifying the following equation

$$\frac{\partial J}{\partial {σ}^{2}} = 0$$

which yields to:

$${\sum }_{i = 1}^{{N}_{bins}} [ {z}_{i} - Q ( \frac{θ + ( i - 1 ) Δ - {m}_{0}}{\sqrt{{σ}^{2}}} ) + Q ( \frac{θ + i Δ - {m}_{0}}{\sqrt{{σ}^{2}}} ) ] \cdot [ f ( i , {σ}^{2} ) - f ( i - 1 , {σ}^{2} ) ] = 0 \\ where f ( i , {σ}^{2} ) = ( θ + i Δ - {m}_{0} ) {e}^{( - \frac{{( θ + i Δ - {m}_{0} )}^{2}}{2 {σ}^{2}} )} \qquad ( 11 )$$

Since the Q(.) function can be approximated with exponential functions, the most computationally expensive part of this equation can be tabulated and a look up table can be built in order to minimize complexity. By solving this equation, the variance σest2 of the Gaussian probability density function that fits the best the empirical probability density function can be found.

The estimated variance of the received samples y[k] of the group corresponds (404) thus to σest2.

An optional, yet additional, calculation of the average of the selected samples is then possible. This new average calculation is more precise than the coarse calculation. This new calculation uses the estimated variance σest2. It can be found by solving the following equation:

$${\sum }_{i = 1}^{{N}_{bins}} {C}_{i} = Q ( \frac{θ - {m}_{1}}{\sqrt{{σ}_{est}^{2}}} ) ⇒ {m}_{1} ( ts ) = θ - \sqrt{{σ}_{est}^{2}} {Q}^{- 1} ( {\sum }_{i = 1}^{{N}_{bins}} {C}_{i} ) \qquad ( 12 )$$

As previously stated, the inverse of the Q function can be pre-computed and stored in a look-up table.

As seen in FIG. 4 in dotted line, steps 403 and 404 can be performed iteratively. The number of iterations depends on a compromise between a desired precision on the SINR calculation and the iterative calculation duration.

Finally, the SINR (405) can be obtained from these calculations. The SINR is computed every TTI (Transmission Time Interval) (one TTI=3 HSDPA slots). Each TTI is lasting 2 ms. This yields the possibility of average the SINR over this period. And the SINR for slot is can be computed as:

$$SINR [ ts ] = \frac{m {1}^{2} [ ts - 2 ] + m {1}^{2} [ ts - 1 ] + m {1}^{2} [ ts ]}{{σ}_{est}^{2} ( ts )} \qquad ( 13 )$$

over the last three slots.

In other words, with a selection that is easy to compute cf. (8), the SINR estimation is more accurate and the curve fitting method enables the best performance among the other methods as will be stated in the following.

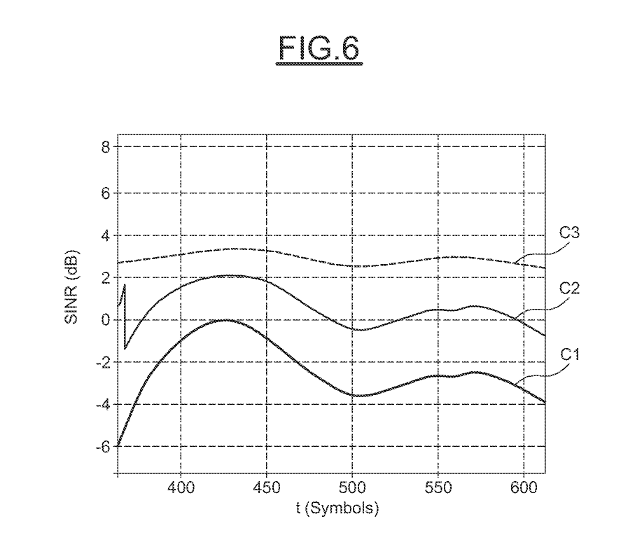

An example of results of a curve fitting process is now illustrated on FIGS. 5 and 6.

On FIG. 5, an empirical simulation histogram of a 2-PAM received signal with a low SINR (10 dB) is illustrated.

The samples of FIG. 5 in the zone around the value zero are affected by a severe intersymbol interference. It is thus difficult to determine the value of the symbol corresponding to the received sample.

To avoid this problematic zone, the selection (8) as described above enables the distinction of three zones. These three zones can be named: more reliable samples, less reliable samples and more reliable samples. As seen earlier, the curve fitting method uses only the samples selected in at least one of the two groups named “more reliable samples”.

In FIG. 6, three curves are represented, each corresponding to different SINR estimation or calculation.
Curve C1 corresponds to a calculated reference SINR.

The reference SINR can be calculated as follow:

$${r}_{d , l} [ k ] = {d}_{l} [ k ] ( {\sum }_{m = 1}^{SF} \{ {g}_{d} [ k + m ] \} + {ISI}_{d , l} [ k + m ] ) + ISI [ k ] + \tilde{n} [ k ] \qquad ( 14 )$$

The main useful part of the data is given by the data symbol d₁[k] weighted with the principal tap g_{d}[k+m] of the convolution of the channel and the equalizer for each chip k. The constructive intersymbol interference given by the pre- and post cursors ISI_{d,1}[k+m] is considered as a useful term. However, this contribution is in general negligible.

The distortion is given by the intersymbol interference of other users and the filtered noise.

The computation of the average SINR in one slot:

$${SINR}_{ref} = \frac{1}{160 {N}_{codes}} {\sum }_{l = 1}^{{N}_{codes}} {\sum }_{ki = 1}^{160} \frac{{( {\sum }_{m = 0}^{SF - 1} \frac{ e \{ {g}_{d} [ k + m ] \}}{SF} )}^{2}}{{( {r}_{d , l} [ k ] - {\sum }_{m = 0}^{SF - 1} \frac{ e \{ {g}_{d} [ k + m ] \}}{SF} {d}_{l} [ k ] )}^{2}} \qquad ( 15 )$$

For simplicity each of the 160*Ncodes transmitted chip is called d[k] and the received data rd[k]. The SINRref can be then written as:

$${SINR}_{ref} = \frac{1}{160 \cdot {N}_{codes}} {\sum }_{k = 1}^{160 \cdot {N}_{codes}} \frac{{( A [ k ] )}^{2}}{{( {r}_{d} [ k ] - A [ k ] d [ k ] )}^{2}} \qquad ( 16 )$$

Curve C2 corresponds to a SINR estimated with the above described method of curve fitting with only one iteration in the dotted loop of FIG. 5.
Curve C3 corresponds to a SINR estimated with a conventional ML (maximum likelihood) method.

The simulation conditions are the following ones:
VA 30, Ior/Ioc=10 dB, Ec/Ior=−6 dB and Ncodes=5 where:
VA 30 is corresponding to a wireless channel of a 30 km/h moving car,
Ior/Ioc is a factor representing the division between the energy received from the synchronized base station and the interference base stations,
Ec/Ior is a factor representing the division between the energy by information compared to the energy received from the synchronized base station.

As illustrated the curve fitting with selection algorithm shows the best performance, i.e. it has the smallest NMSE (Normalized Mean Square Error) with the reference SINR.

In other words, SINR calculated from the curve fitting method (with only one iteration in the dotted loop of FIG. 3), is the closest to the reference SINR. This SINR is also less overestimated.

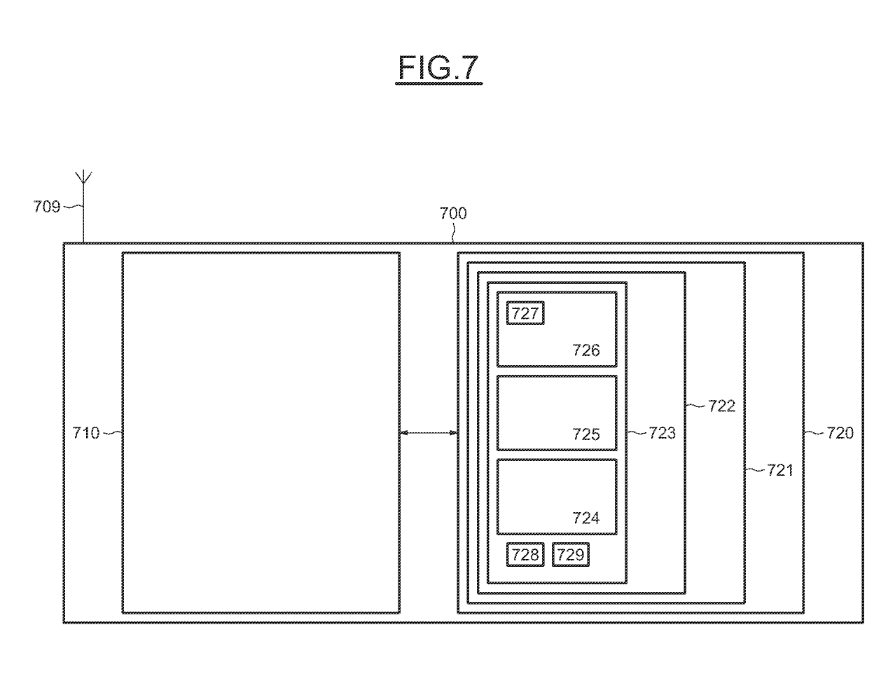

FIG. 7 illustrates diagrammatically a wireless apparatus 700 including a device 722 capable of implementing a curve fitting process according to the above-described method. This device may be also incorporated in a software manner in the base-band processor of the wireless apparatus of FIG. 3. The device comprises processing means 723 for determining SINR using curve fitting.

The processing means 723 comprise selection means 724 for selecting a set of samples from the reception means, first calculation means 725 for performing an average calculation and second calculation means 726 for performing a variance calculation.

The first calculation and/or said second calculation means, respectively 725, 726, are configured to use only the selected set of samples from the selection means 724.

In one embodiment, the selection means 724 can be configured to withdraw the samples subjected to interference intersymbol for obtaining at least one group of samples. The second calculation means 726 can then comprise means 727 for curve fitting the said at least one group of samples with minimum squared error.

Advantageously, the means 727 for curve fitting can be configured to curve fit the said at least one group of samples with a Gaussian.

According to another embodiment, the processing means 723 can comprise third calculation means 728 for performing a supplementary average calculation of the said at least one group of samples. This calculation is done using the variance calculated by the second calculation means 726.

Finally, the processing means 723 can also comprise control means 729 for iteratively activating the means 727 for curve fitting and the third calculation means 728.

The device, the processing means comprised and the others means described above may be realized by software modules within the base-band processor.

1-15. (canceled)

16. A method of estimating a signal to interference plus noise ratio (SINR) of an incident signal on a time interval, the method comprising:
receiving samples of the incident signal during the time interval; and
determining the SINR from the received samples using an average calculation and a variance calculation, wherein determining comprises:
selecting a set of samples from the received samples; and
performing at lease one of the average calculation and the variance calculation by using only the selected set of samples, wherein the selected set of samples comprises fewer samples than the number of samples in the received samples.

17. The method according to claim 16, wherein the incident signal is a modulated signal and both the average calculation and the variance calculation are performed using only the selected set of samples; and further comprising obtaining maximum likelihood values of certain samples from a position of the certain samples in a modulation constellation and a known sequence of transmitted reference samples.

18. The method according to claim 17, wherein the selection step is performed iteratively until the difference between a current average value of samples calculated on a current selected set of samples and a preceding average value of samples calculated on the preceding selected set of samples is smaller than a threshold.

19. The method according to claim 16, wherein selecting comprises withdrawing samples subjected to an interference intersymbol in order to obtain the set of samples, and wherein the variance calculation is based on a curve fitting with minimum squared error on the set of samples.

20. The method according to claim 19, wherein the curve is Gaussian.

21. The method according to claim 19, further comprising performing a supplementary average calculation on the set of samples using the result of the variance calculation.

22. The method according to claim 21, wherein the curve fitting step and the supplementary average calculation are performed iteratively, and wherein a current variance calculation uses a result of a preceding supplementary average calculation.

23. A device for estimating a signal to interference plus noise ratio (SINR) of an incident signal on a time interval, the device comprising:
a receiver configured to receive samples of the incident signal during the interval;
a processor adapted to estimate the SINR from the received samples, the processor comprising:
a selection block configured to select a set of samples from the received samples;
a first calculation block configured to perform an average calculation using only the set of samples; and
a second calculation block configured to perform a variance calculation using only the set of samples.

24. The device according to claim 23, wherein the incident signal is a modulated signal, and the first calculation block an second calculation block are configured to use maximum likelihood values of the set of samples and a known sequence of transmitted reference samples, wherein each maximum likelihood value of each sample of the set of samples is obtained based on a position of each sample in the modulated signal's modulation constellation.

25. The device according to claim 24, wherein the selection block comprises:
a comparison block adapted to compare a difference between a current average value of samples calculated using a current set of samples and a preceding average value of samples calculated using a preceding set of samples; and
a control block configured to activate the selection means until the difference is less than a threshold.

26. The device according to claim 23, wherein the selection block is configured to withdraw at least one sample determined to be subjected to intersymbol interference from the received samples in order to create the set of samples, and wherein the second calculation block comprises a curve fitting block adapted to curve fit the set of samples to minimum squared error curve.

27. The device according to claim 26, wherein the curve fitting block is configured to curve fit the set of samples with a Gaussian curve.

28. The device to claim 26, wherein the processor further comprises a third calculation block configured to perform a supplementary average calculation of the set of samples using a variance result calculated by the second calculation block.

29. The device according to claim 28, wherein the processor further comprises a control block that iteratively activates the curve fitting block and the third calculation block.

30. The device according to claim 23, wherein a wireless communication apparatus comprises the device.
